(19) United States
(12) Patent Application Publication
(10) Pub. No.: US 2022/0170771 A1
(43) Pub. Date: Jun. 2, 2022

(54) PHYSICAL QUANTITY MEASURING DEVICE

(71) Applicant: DENSO CORPORATION, Kariya-City (JP)

(72) Inventor: Hiroyuki AKUZAWA, Kariya-city (JP)

(21) Appl. No.: 17/671,796

(22) Filed: Feb. 15, 2022

Related U.S. Application Data
(63) Continuation of application No. PCT/JP2020/030378, filed on Aug. 7, 2020.

(30) Foreign Application Priority Data
Sep. 23, 2019 (JP) 2019-172384

(51) Int. Cl. G01F 1/684

(52) U.S. Cl. CPC G01F 1/684

(57) ABSTRACT

A physical quantity measuring device includes a housing having a part disposed in a main passage through which a measurement target fluid flows, a sensing element configured to detect a physical quantity of the measurement target fluid, a circuit board disposed in the housing and having a mounting area on which the sensing element is mounted, a potting resin covering an electric connecting portion between the circuit board and the sensing element; and a restricting portion disposed on the circuit board in a vicinity of the mounting area to restrict the potting resin from wetting and spreading out.

### CROSS REFERENCE TO RELATED APPLICATION

The present application is a continuation application of International Patent Application No. PCT/JP2020/030378 filed on Aug. 7, 2020, which designated the U.S. and claims the benefit of priority from Japanese Patent Application No. 2019-172384 filed on Sep. 23, 2019. The entire disclosures of all of the above applications are incorporated herein by reference.

### TECHNICAL FIELD

The present disclosure relates to a physical quantity measuring device that measures a physical quantity of a measurement target fluid.

### BACKGROUND

There is a physical quantity measuring device that includes a housing disposed in a main passage through which a measurement target fluid flows, a circuit board and a plurality of sensing elements. In order to downsize the housing, the circuit board is insert-molded into the housing and the plurality of sensing elements are mounted on both sides of the circuit board.

### SUMMARY

A physical quantity measuring device includes a housing having a part disposed in a main passage thorough which a measurement target fluid flows, a sensing element configured to detect a physical quantity of the measurement target fluid, a circuit board disposed in the housing and having a mounting area on which the sensing element is mounted, a potting resin covering an electric connecting portion between the circuit board and the sensing element, and a restricting portion disposed on the circuit board in a vicinity of the mounting area to restrict the potting resin from wetting and spreading out.

### BRIEF DESCRIPTION OF DRAWINGS

FIG. 1 is a schematic view of a physical quantity measuring device according to a first embodiment viewed from an upstream side of the physical quantity measuring device in an airflow direction.

FIG. 2 is a cross-sectional view taken along a line II-II of FIG. 1.

FIG. 3 is a schematic view illustrating an internal structure of the physical quantity measuring device according to the first embodiment.

FIG. 4 is a cross-sectional view taken along a line IV-IV of FIG. 3.

FIG. 5 is a schematic cross-sectional view illustrating a part of a physical quantity measuring device of a comparative example.

FIG. 6 is a cross-sectional view taken along a line VI-VI of FIG. 3.

FIG. 7 is a schematic cross-sectional view illustrating a first modification of the physical quantity measuring device according to the first embodiment.

FIG. 8 is a schematic cross-sectional view illustrating a second modification of the physical quantity measuring device according to the first embodiment.

FIG. 9 is a schematic cross-sectional view illustrating a third modification of the physical quantity measuring device according to the first embodiment.

FIG. 10 is a schematic cross-sectional view illustrating a part of a physical quantity measuring device according to a second embodiment.

FIG. 11 is a schematic cross-sectional view illustrating a part of a physical quantity measuring device according to a third embodiment.

FIG. 12 is a schematic cross-sectional view illustrating a part of a physical quantity measuring device according to a fourth embodiment.

FIG. 13 is an explanatory diagram for explaining a wet spread of a potting resin.

FIG. 14 is a schematic cross-sectional view illustrating a part of a physical quantity measuring device according to a fifth embodiment.

FIG. 15 is a schematic cross-sectional view illustrating a modification of the physical quantity measuring device according to the fifth embodiment.

FIG. 16 is a schematic cross-sectional view illustrating a part of a physical quantity measuring device according to a sixth embodiment.

FIG. 17 is a schematic cross-sectional view illustrating a modification of the physical quantity measuring device according to the sixth embodiment.

FIG. 18 is a schematic diagram illustrating an internal structure of a physical quantity measuring device according to a seventh embodiment.

FIG. 19 is a schematic diagram illustrating an internal structure of a physical quantity measuring device according to an eighth embodiment.

### DESCRIPTION OF EMBODIMENTS

To begin with, examples of relevant techniques will be described.

There is a physical quantity measuring device that includes a housing disposed in a main passage through which a measurement target fluid flows, a circuit board and a plurality of sensing elements. In order to downsize the housing, the circuit board is insert-molded into the housing and the plurality of sensing elements are mounted on both sides of the circuit board.

In the physical quantity measuring device, the present inventors consider filling an electric connecting portion between the circuit board and the sensing elements with a potting resin in order to strengthen and protect the connecting portion.

According to the study by the present inventors, when the potting resin is used for connecting the sensing elements, other components cannot be arranged near the sensing elements in consideration of wet spread of the potting resin and variations of the wet edge of the potting resin. Thus, it is difficult to avoid increasing the size of the circuit board. Increasing the size of the circuit board is not preferable because it leads to the increase in the size of the physical quantity measuring device.

It is objective of the present disclosure to provide a physical quantity measuring device that can avoid increasing the size of the circuit board even if a potting resin is used to connect sensing elements.

According to an aspect of the present disclosure, a physical quantity measuring device includes a housing having a part disposed in a main passage thorough which a measurement target fluid flows, a sensing element configured to detect a physical quantity of the measurement target fluid, a circuit board disposed in the housing and having a mounting area on which the sensing element is mounted, a potting resin covering an electric connecting portion between the circuit board and the sensing element, and a restricting portion disposed on the circuit board in a vicinity of the mounting area to restrict the potting resin from wetting and spreading out.

According to this, since the wet spread of the potting resin is restricted by the restricting portion provided on the circuit board, the size of the circuit board does not increase due to the wet spread of the potting resin and variations of the wet edge of the potting resin. Therefore, according to the physical quantity measuring device of the present disclosure, it is possible to suppress the increase in the size of the circuit board even if a potting resin is used for connecting the sensing elements.

Here, the “wet spread of the potting resin” is the spread of the wet edge that changes according to the wettability of the potting resin to the circuit board. The wet edge is the outer edge of a contact portion of the potting resin that is in contact with the circuit board.

Hereinafter, embodiments of the present disclosure will be described with reference to the drawings. In the following embodiments, portions that are the same as or equivalent to those described in the preceding embodiments are denoted by the same reference numerals, and a description of the same or equivalent portions may be omitted. In addition, when only a part of the components is described in the embodiment, the components described in the preceding embodiment can be applied to other parts of the components. The following embodiments may be partially combined with each other even if such a combination is not explicitly described as long as there is no disadvantage with respect to such a combination.

### First Embodiment

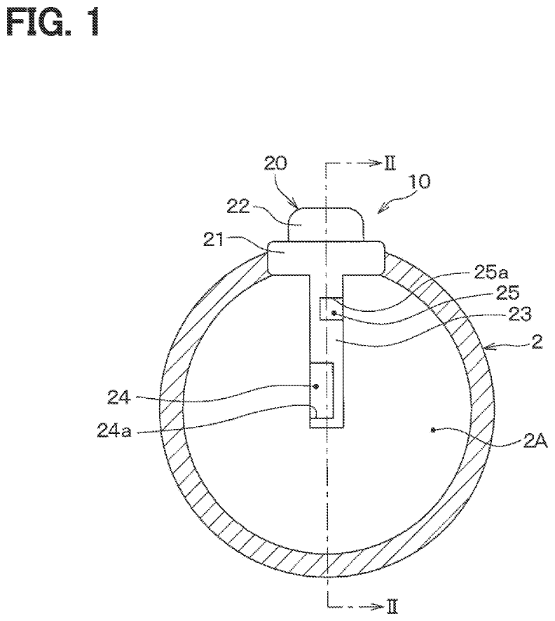

The present embodiment will be described with reference to FIGS. 1 to 6. In this embodiment, an example in which a physical quantity measuring device 10 of the present disclosure is applied to an internal combustion engine control system that controls an internal combustion engine will be described. The physical quantity measuring device 10 of the present embodiment uses an intake air sucked into the internal combustion engine as a measurement target fluid, and measures a physical quantity of the measurement target fluid. The internal combustion engine control system controls a flow rate of the measurement target fluid to be supplied into the internal combustion engine by adjusting an opening degree of a throttle valve (not shown) according to measurement results of the physical quantity measuring device 10.

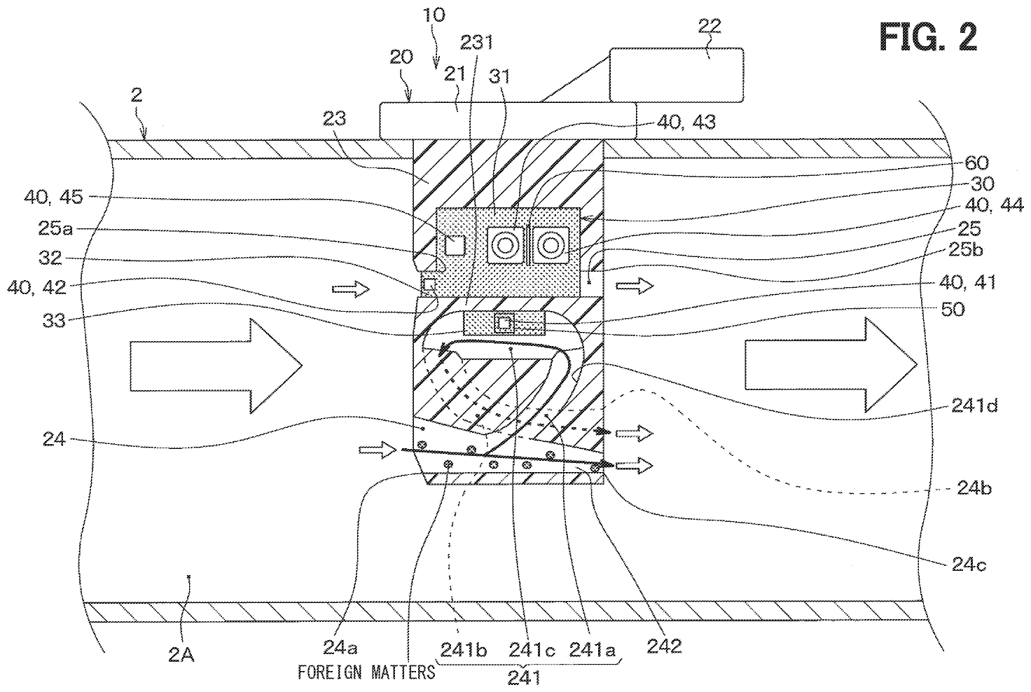

As shown in FIGS. 1 and 2, the physical quantity measuring device 10 is attached to an intake pipe 2 through which intake air, which is a measurement target fluid, flows. The intake pipe 2 is a cylindrical pipe defining a main passage 2A through which the measurement target fluid flows. The intake pipe 2 is not limited to the cylindrical pipe, and may be formed of, for example, a square tubular pipe.

The physical quantity measuring device 10 has a housing 20 forming a housing portion. At least a part of the housing 20 is arranged in the main passage 2A. The housing 20 has a flange 21 for fixing the physical quantity measuring device 10 to the intake pipe 2, an external connector 22 exposed to the outside from the flange 21 for electrically connecting between the physical quantity measuring device and an external device, and a measuring portion 23 protruding from the flange 21 toward a center of the main passage 2A.

The flange 21 is fit into a mounting hole provided in the intake pipe 2. The flange 21 has a lower surface exposed to the main passage 2A. The lower surface of the flange 21 is easily affected by the heat of the main passage 2A. Therefore, it is desirable that the lower surface of the flange 21 that is exposed to the main passage 2A defines a recess and the like to inhibit the heat from transmitting between the main passage 2A and the flange 21.

The external connector 22 is provided on the upper surface of the flange 21 and protrudes from the flange 21 toward the downstream side of the physical quantity measuring device 10 in the flow direction of the measurement target fluid. The external connector 22 connects the physical quantity measuring device 10 to a control device of the internal combustion engine control system (not shown). Information indicating measurement results is output from the physical quantity measuring device 10 to the outside via the external connector 22. Further, electric power for driving the physical quantity measuring device 10 is supplied to the physical quantity measuring device 10 via the external connector 22. The external connector 22 is not limited to one that protrudes toward the downstream side in the flow direction of the measurement target fluid, but may be one that protrudes toward the upstream side or one that protrudes upward.

The measuring portion 23 has a shape that a front surface viewed in the airflow direction has a substantially rectangular shape whose width is narrower than the height. The measuring portion 23 defines, therein, a fluid passage through which the measuring target fluid flows and houses sensing elements 40 for measuring physical quantities of the measuring target fluid.

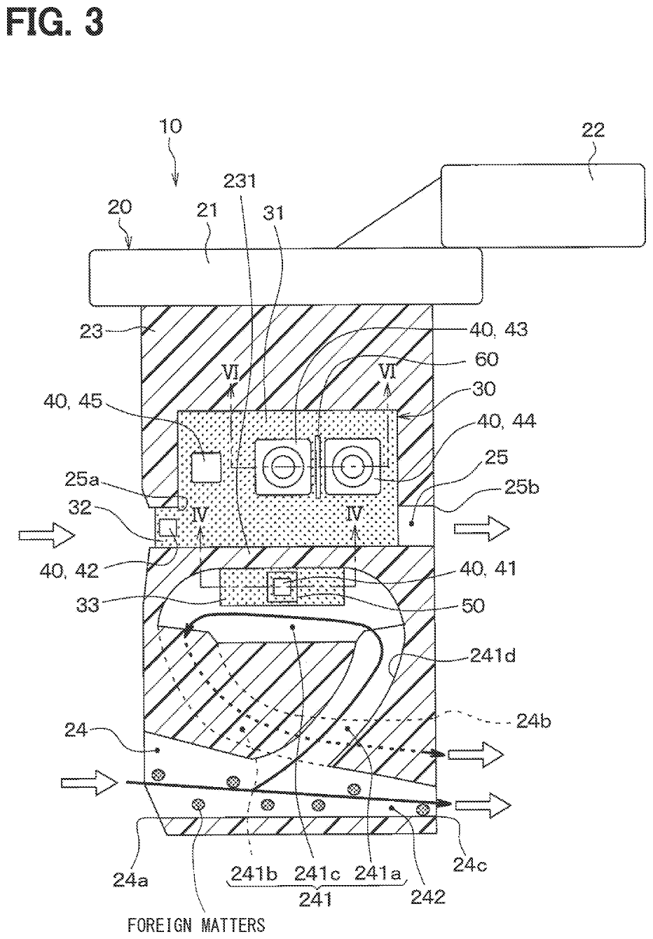

As shown in FIGS. 2 and 3, the measuring portion 23 defines a first sub-passage 24 and a second sub-passage 25. A part of the measurement target fluid flowing through the main passage 2A flows through the first sub-passage 24 and the second sub-passage 25. The first sub-passage 24 and the second sub-passage 25 are formed, for example, of a combination of a groove formed on a main body of the housing 20 and a cover covering the groove. The measuring portion 23 has a partition 231 partitioning the first sub-passage 24 from the second sub-passage 25. The first sub-passage 24 and the second sub-passage 25 may be formed by through holes.

The measuring portion 23 defines, in a distal end portion of the measuring portion 23, a first inlet portion 24a for introducing a part of the measurement target fluid into the first sub-passage 24, a first outlet portion 24b for returning the measuring target fluid from the first sub-passage 24 to the main passage 2A, and a discharging portion 24c.

The first sub-passage 24 has a sub main passage 241 through which the measurement target fluid introduced into the first sub-passage 24 through the first inlet portion 24a flows and a sub branching passage 242 branching off from the sub main passage 241. A part of the measurement target fluid flowing through the sub main passage 241 flows through the sub branching passage 242.

The sub main passage 241 includes an upstream passage 241a located close to one side surface of the measuring portion 23, a downstream passage 241b located close to the other side surface of the measuring portion 23, and a connecting passage 241c fluidly connecting between the upstream passage 241a and the downstream passage 241b. The one side surface is opposite to the other side surface of the measuring portion 23.

The upstream passage 241a extends from the first inlet portion 24a toward the downstream side in the flow direction of the measurement target fluid. The sub branching passage 242 branches off from an intermediate position of the upstream passage 241a. The upstream passage 241a is curved from a branch portion with the sub branching passage 242 toward the flange 21 and toward the downstream side of the physical quantity measuring device 10. The upstream passage 241a is in communication with the connecting passage 241c in the vicinity of a downstream wall of the measuring portion 23. That is, the upstream passage 241a has a curved portion 241d that curves away from the sub branching passage 242.

The connecting passage 241c extends in the thickness direction of the measuring portion 23 (that is, in the direction perpendicular to the paper surface of FIGS. 2 and 3). The circuit board 30 has a protruding portion 33 disposed in the connecting passage 241c. The protruding portion 33 passes through the partition 231 of the measuring portion 23 and protrudes into the connecting passage 241c.

The downstream passage 241b is curved from the first outlet portion 24b toward the flange 21 and toward the upstream side of the physical quantity measuring device 10. The downstream passage 241b is in communication with the connecting passage 241c in the vicinity of an upstream wall of the measuring portion 23.

The sub main passage 241 has the upstream passage 241a, the connecting passage 241c, and the downstream passage 241b as described above, so that the measurement target fluid introduced into the measuring portion 23 through the first inlet portion 24a turns once and then flows out through the first outlet portion 24b.

The sub branching passage 242 is a passage connecting the branch portion with the sub main passage 241 and the discharging portion 24c. The sub branching passage 242 extends linearly from the branch portion with the sub main passage 241 toward the discharging portion 24c along the flow direction of the measurement target fluid. The sub branching passage 242 is disposed for discharging large-mass foreign matters (for example, water, dust, oil, etc.), which have entered the first sub-passage 24 through the first inlet portion 24a, to the discharging portion 24c through the sub branching passage 242.

A flow rate detector 41 constituting one of the sensing elements 40 is arranged in the intermediate position of the first sub-passage 24. The flow rate detector 41 is arranged in the sub main passage 241 of the first sub-passage 24 having the curved portion 241d. The details of the flow rate detector 41 will be described later.

Further, the measuring portion 23 defines a second inlet portion 25a and a second outlet portion 25b in an intermediate portion of the measuring portion 23 between the first sub passage 24 and the flange 21. A part of the measurement target fluid is introduced into the second sub passage 25 through the second inlet portion 25a. The measurement target fluid is returned to the main passage 2A from the second sub passage 25 through the second outlet portion 25b.

A temperature detector 42 constituting one of the sensing elements 40 is disposed at a position upstream of the second inlet portion 25a of the second sub passage 25. The temperature detector 42 constitutes one of the sensing elements 40 that detect physical quantities of the measurement target fluid flowing through the main passage 2A.

The temperature detector 42 is arranged on the surface of the circuit board 30 built in the measuring portion 23. The temperature detector 42 is provided on a tongue piece portion 32 of the circuit board 30. The temperature detector 42 has a chip-type temperature sensor and is electrically connected to the circuit board 30. Although not shown, an electric connecting portion between the circuit board 30 and the temperature detector 42 is covered with a potting resin. The potting resin in a molten state is coated to the electric connecting portion between the temperature detector 42 and the circuit board 30, and solidifies after the coating to cover the temperature detector 42. As a result, the electric connecting portion between the circuit board 30 and the temperature detector 42 is protected by the potting resin. The potting resin can generally be handled in a liquid state and solidifies at room temperature, and examples thereof include epoxy resin, silicone resin, fluorocarbon resin, urethane resin, and the like.

The second inlet portion 25a is continuously formed on the downstream side of the temperature detector 42. As a result, the measurement target fluid flowing into the second sub passage 25 through the second inlet portion 25a contacts with the temperature detector 42 first and then flows into the second inlet portion 25a. When the measurement target fluid contacts the temperature detector 42, the temperature of the measurement target fluid is detected. The measurement target fluid having contacted the temperature detector 42 flows into the second sub passage 25 through the second inlet portion 25a, flows through the second sub passage 25, and flows out to the main passage 2A through the second outlet portion 25b.

Further, in an intermediate portion of the second sub-passage 25, a first pressure detector 43, a second pressure detector 44, and a humidity detector 45 forming the sensing elements 40 are arranged. In the second sub-passage 25, the humidity detector 45, the first pressure detector 43, and the second pressure detector 44 are arranged in this order from the upstream side to the downstream side in the flow direction of the measurement target fluid.

The first pressure detector 43, the second pressure detector 44, and the humidity detector 45 are disposed on the surface of the circuit board 30. Specifically, the first pressure detector 43, the second pressure detector 44, and the humidity detector 45 are arranged in an upper area of the circuit board 30 that is located upper than the second inlet portion 25a and the second outlet portion 25b of the second sub passage 25. The first pressure detector 43, the second pressure detector 44, and the humidity detector 45 are electrically connected to the circuit board 30 by, for example, soldering.

The humidity detector 45 has a chip-type humidity sensor and is electrically connected to the circuit board 30. Although not shown, an electric connecting portion between the circuit board 30 and the humidity detector 45 is covered with a potting resin. The potting resin in a molten state is applied to the electric connecting portion between the circuit board 30 and the humidity detector 45, and then solidifies to cover the humidity detector 45. As a result, the electric connecting portion between the circuit board 30 and the humidity detector 45 is protected by the potting resin. The potting resin can generally be handled in a liquid state and solidifies at room temperature, and examples thereof include epoxy resin, silicone resin, fluorocarbon resin, urethane resin, and the like.

The first pressure detector 43 is arranged closer to the second pressure detector 44 than to the humidity detector 45. That is, the first pressure detector 43 and the second pressure detector 44 are arranged adjacent to each other in a main body portion 31 of the circuit board 30. Details of the first pressure detector 43 and the second pressure detector 44 will be described later.

The circuit board 30 is integrally molded inside the measuring portion 23 by insert molding. In FIGS. 2 and 3, a portion indicating the circuit board 30 is hatched with a dot-pattern to distinguish the circuit board 30 from the housing 20. It should be noted that the actual circuit board 30 is not provided with a dot pattern.

The sensing elements 40 for measuring various physical quantities of the measurement target fluid flowing through the main passage 2A are mounted on the circuit board 30. Although not shown, the circuit board 30 has a circuit unit for processing signals detected by the sensing elements 40.

The circuit board 30 is provided at a position of the measuring portion 23 close to the flange 21. The circuit board 30 has a flat plate shape. The circuit board 30 includes the main body portion 31, the tongue piece portion 32 protruding from the main body portion 31 toward the upstream side in the flow direction of the measurement target fluid, and the protruding portion 33 protruding from the main body portion 31 toward the distal end of the measuring portion 23.

The sensing elements 40 are mounted on the front surface of the circuit board 30, and a microprocessor or the like constituting the circuit unit is mounted on the back surface of the circuit board 30. A part of the sensing elements 40 may be mounted on the back surface of the circuit board 30.

The main body portion 31 has a substantially rectangular shape in a plan view. At least a part of the main body portion 31 is positioned in the second sub-passage 25. In the main body portion 31, at least a portion where the sensing elements 40 are mounted is exposed to the second sub-passage 25. The first pressure detector 43, the second pressure detector 44, and the humidity detector 45 are mounted on the main body portion 31.

The tongue piece portion 32 forms a part of the circuit board 30, and is integrally formed with the main body portion 31. The tongue piece portion 32 protrudes from the second inlet portion 25a of the second sub-passage 25 toward the upstream side in the flow direction of the measurement target fluid. The temperature detector 42 is mounted on the tongue piece portion 32.

Here, the measuring portion 23 has an upstream wall located on an upstream side in the flow direction of the measurement target fluid and a recess recessed from the upstream wall toward the downstream side. The second inlet portion 25a is formed inside the recess and the tongue piece portion 32 is arranged inside the recess.

The protruding portion 33 forms a part of the circuit board 30, and is integrally formed with the main body portion 31. The protruding portion 33 is positioned in the first sub-passage 24. The protruding portion 33 has a portion where the sensing element 40 is mounted and the portion is exposed to the first sub-passage 24. The flow rate detector 41 is mounted on the protruding portion 33.

The flow rate detector 41 is an element that detects the flow rate of the measurement target fluid. As the flow rate detector 41, for example, a heat flow type flow meter can be adopted. The flow rate detector 41 may be a flow rate detector other than the heat flow type flow meter.

The flow rate detector 41 is provided on the front surface of the circuit board 30. The flow rate detector 41 is provided on the protruding portion 33 of the circuit board 30. The flow rate detector 41 is electrically connected to the protruding portion 33 of the circuit board 30 by wire bonding or the like.

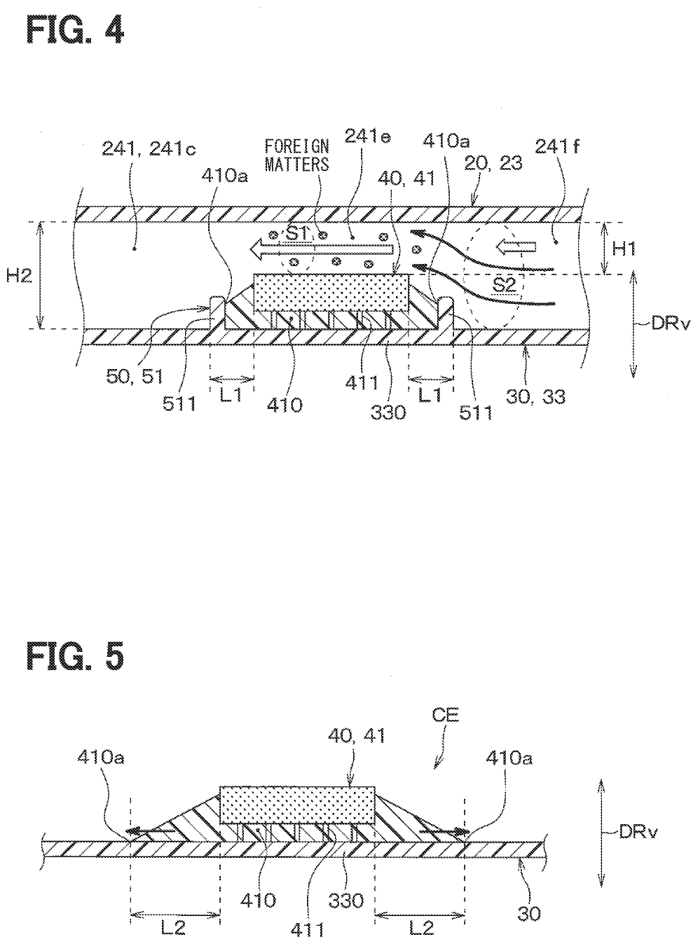

As shown in FIG. 4, the electric connecting portion 411 between the flow rate detector 41 and the circuit board 30 is covered with the potting resin 410. The potting resin 410 in a molten state is applied to the electric connecting portion 411 between the circuit board 30 and the flow rate detector 41, and then solidifies to cover the connecting portion 411. As a result, the electric connection portion 411 between the circuit board 30 and the flow rate detector 41 is protected by the potting resin 410. The potting resin 410 can generally be handled in a liquid state and solidifies at room temperature, and examples thereof include epoxy resin, silicone resin, fluorocarbon resin, urethane resin, and the like.

Here, FIG. 5 is a schematic cross-sectional view illustrating the vicinity of the flow rate detector 41 of a physical quantity measuring device CE of a comparative example of the present embodiment. The physical quantity measuring device CE of the comparative example uses the potting resin 410 for connecting the flow rate detector 41 to the flat circuit board 30. In this type of physical quantity measuring device CE, the wet edge of the potting resin 410 tends to spread outward. Further, since the surface tension of the potting resin 410 is affected by the environmental temperature at the time of manufacture, variations in the wet-spread and the wet edge of the potting resin 410 are likely to occur.

Therefore, when the potting resin 410 is used to connect the flow rate detector 41 to the flat circuit board 30, it is difficult to arrange other components near the flow rate detector 41 in consideration of variations in the wet spread and the wet edge 410a of the potting resin 410. This is not preferable because it leads to an increase in the size of the circuit board 30.

Therefore, as shown in FIG. 4, the physical quantity measuring device 10 of the present embodiment has a first restricting portion 50 configured to restrict the potting resin 410 from wetting and spreading out. The first restricting portion 50 is disposed around a mounting area 330 of the protruding portion 33 of the circuit board 30 on which the flow rate detector 41 is mounted. That is, the first restricting portion 50 is disposed to surround the entire circumference of the mounting area 330. Then, the inside of the first restricting portion 50 is filled with the potting resin 410. Specifically, at least a part of the first restricting portion 50 is in contact with the potting resin 410.

The first restricting portion 50 is formed of a first stepped portion 51. When a direction perpendicular to the plate surface of the circuit board 30 is defined as a plate vertical direction DRv, the first stepped portion 51 causes the mounting area 330 to have a different height in the plate vertical direction DRv from that of the vicinity of the mounting area 330. The first stepped portion 51 protrudes toward the flow rate detector 41 from the vicinity of the mounting area 330 beyond the mounting area 330 in the plate vertical direction DRv. That is, the first stepped portion 51 is a first protrusion 511 that surrounds the mounting area 330.

The first stepped portion 51 is disposed on the circuit board 30 such that the distance L1 between the outer surface of the first protrusion 511 and the side surface of the flow rate detector 41 is less than the distance L2 between the wet edge 410a of the potting resin 410 and the side surface of the flow rate detector 41 when the first protrusion 511 is not disposed on the circuit board 30.

Specifically, the first protrusion 511 is integrally formed with the circuit board 30. The first protrusion 511 is formed at a position away from the mounting area 330 by a predetermined distance so as not to be in direct contact with the flow rate detector 41. For example, the height of the first protrusion 511 in the plate vertical direction DRv is set to be lower than that of the flow rate detector 41. Further, the plate width of the first protrusion 511 is set to be thinner than the width of the potting resin 410 located between the first protrusion 511 and the flow rate detector 41.

Here, the sub main passage 241 has an arranging portion 241e in which the flow rate detector 41 is arranged, and the flow rate detector 41 is arranged to protrude toward a center of the sub main passage 241. Thus, a passage width H1 of the arranging portion 241e is less than a passage width H2 of an upstream portion 241f of the sub main passage 241 that is located upstream of the arranging portion. As a result, in the first sub-passage 24, the passage area S1 of the arranging portion 241e in which the flow rate detector 41 is arranged is less than the passage area S2 of the upstream portion 241f that is located upstream of the arranging portion 241e. That is, in the sub main passage 241, a passage area of the arranging portion 241e of the flow rate detector 41 is reduced.

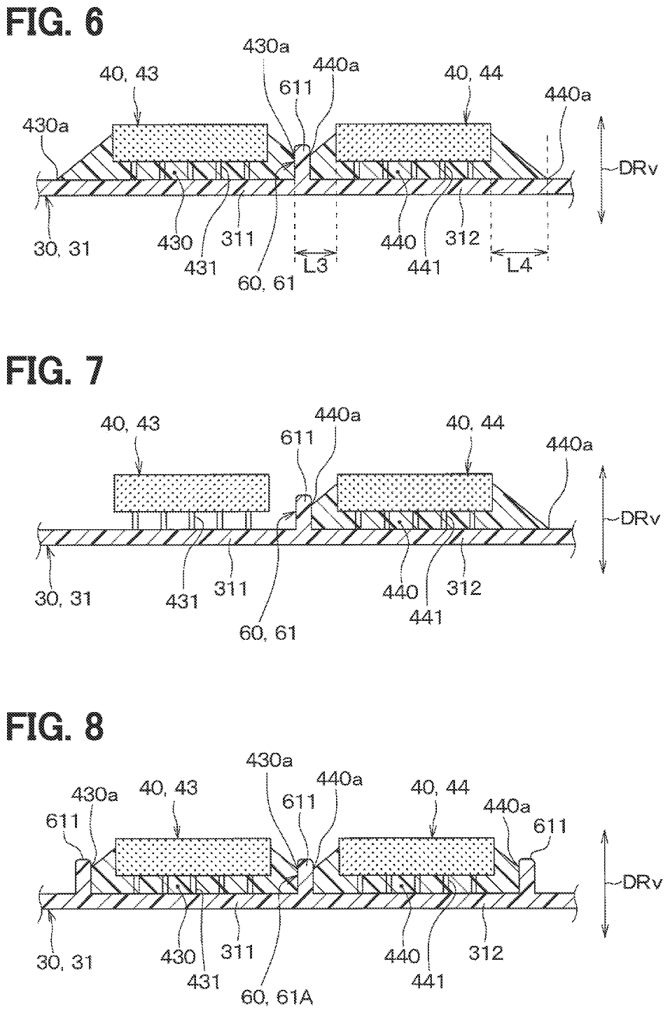

Next, the details of the first pressure detector 43 and the second pressure detector 44 will be described with reference to FIG. 6. As shown in FIG. 6, an electric connecting portion 431 between the first pressure detector 43 and the circuit board 30 and an electric connecting portion 441 between the second pressure detector 44 and the circuit board 30 are covered with the potting resins 430 and 440, respectively. The potting resins 430, 440 in a molten state are applied respectively to the electric connecting portions 431 and 441 with the circuit board 30, and then solidifies to cover the connecting portions 431 and 441 of the first pressure detector 43 and the second pressure detector 44.

As a result, the electric connecting portion 431 between the first pressure detector 43 and the circuit board 30 and the electric connecting portion 441 between the second pressure detector 44 and the circuit board 30 are protected by the potting resins 430 and 440, respectively. The potting resins 430 and 440 can generally be handled in a liquid state and solidifies at room temperature, and examples thereof include epoxy resin, silicone resin, fluorocarbon resin, and urethane resin, and the like.

The main body portion 31 has a first mounting area 311 on which the first pressure detector 43 is mounted, and a second mounting area 312 on which the second pressure detector 44 is mounted. A second restricting portion 60 is disposed between the first mounting area 311 and the second mounting area 312 to restrict the potting resins 430, 440 from wetting and spreading out. The vicinity of the first mounting area 311 and the vicinity of the second mounting area 312 are overlapped in an overlapping area. The second restricting portion 60 is disposed in the overlapping area. Specifically, at least a part of the second restricting portion 60 is in contact with the potting resins 430 and 440.

The second restricting portion 60 includes a second stepped portion 61 that causes the first mounting area 311 and the second mounting area 312 to have different heights in the plate vertical direction DRv from those of the vicinity of the first mounting area 311 and the second mounting area 312, respectively. The second stepped portion 61 is formed of a second protrusion 611 protruding from a portion between the first mounting area 311 and the second mounting area 312 toward the pressure detectors 43, 44 beyond the first mounting area 311 and the second mounting area 312 in the plate vertical direction DRv.

The second stepped portion 61 is disposed on the circuit board 30 such that the distance L3 between the outer surface of the second protrusion 611 and the side surface of the second pressure detector 44 is less than the distance L4 between the wet edge 440a of the potting resin 440 on a side of the second pressure detector 44 where the second protrusion 611 is not provided and the side surface of the second pressure detector 44. This also applies to the relationship between the second stepped portion 61 and the first pressure detector 43.

Specifically, the second protrusion 611 is integrally formed with the circuit board 30. The second protrusion 611 extends linearly at a position equidistant from both the first mounting area 311 and the second mounting area 312. Further, for example, the height of the second protrusion 611 in the plate vertical direction DRv is lower than that of each of the pressure detectors 43, 44.

Next, the operation of the physical quantity measuring device 10 will be described. The physical quantity measuring device 10 outputs information detected by the sensing elements 40 to the control device of the internal combustion engine control system in response to a request from the control device.

When the internal combustion engine is operating, the intake air, which is the measurement target fluid, flows through the main passage 2A inside the intake pipe 2. When the measurement target fluid flows through the main passage 2A, a part thereof passes through the first sub-passage 24 and the second sub-passage 25 of the physical quantity measuring device 10 as shown in FIGS. 2 and 3.

Specifically, a part of the measurement target fluid is introduced into the first sub-passage 24 through the first inlet portion 24a. Most of the measurement target fluid introduced into the first sub-passage 24 flows into the sub main passage 241, and the rest flows through the sub branching passage 242 and is discharged out of the sub branching passage 242 through the discharging portion 24c together with foreign matters having large mass. It is difficult for foreign matters having large mass to change the course suddenly due to the inertial force. As a result, the foreign matters are likely to flow through the sub branching passage 242 that extends linearly.

The measurement target fluid flowing through the sub main passage 241 flows through the upstream passage 241a to the connecting passage 241c. At this time, the measurement target fluid passes through the vicinity of the flow rate detector 41, so that the flow rate of the measurement target fluid is detected by the flow rate detector 41.

Here, the passage area S1 of the arranging portion 241e in which the flow rate detector 41 is arranged is less than the passage area S2 of the upstream portion located upstream of the arranging portion 241e. According to this, the flow velocity of the measurement target fluid increases in the arranging portion 241e where the flow rate detector 41 is arranged, so that suction action of the high-speed airflow is generated and the foreign matters entering the upstream passage 241a is easily discharged to the downstream side of the flow rate detector 41 together with the measurement target fluid.

After that, the measurement target fluid flowing through the connecting passage 241c flows through the downstream passage 241b. Then, the measurement target fluid returns to the main passage 2A through the downstream passage 241b and the first outlet portion 24b.

Further, a part of the measurement target fluid is introduced into the second sub-passage 25 through the second inlet portion 25a. In the physical quantity measuring device 10, the temperature detector 42 is arranged at an upstream position of the second inlet portion 25a. Therefore, the temperature of the measurement target fluid to be introduced into the second sub-passage 25 is detected by the temperature detector 42.

Most of the measurement target fluid introduced into the second sub-passage 25 flows toward the second outlet portion 25b, and then returns into the main passage 2A through the second outlet portion 25b. At this time, the humidity of the measurement target fluid is detected by the humidity detector 45. Further, the pressure of the measurement target fluid is detected by the first pressure detector 43 and the second pressure detector 44.

Here, the first pressure detector 43, the second pressure detector 44, and the humidity detector 45 are located in the upper area of the circuit board 30 that is located upward of the second inlet portion 25a and the second outlet portion 25b of the second sub passage 25. In other words, the first pressure detector 43, the second pressure detector 44, and the humidity detector 45 are located at positions of the circuit board 30 that are more difficult to see from the second inlet portion 25a and the second outlet portion 25b compared to the temperature detector 42. Therefore, the foreign matters that have entered the second sub-passage 25 is difficult to flow to the positions where the first pressure detector 43, the second pressure detector 44, and the humidity detector 45 are arranged. Since it is difficult for foreign matters having large mass to suddenly change its course due to an inertial force, the foreign matters tend to flow linearly from the second inlet portion 25a to the second outlet portion 25b.

In the physical quantity measuring device 10 described above, the connecting portion 411 between the circuit board 30 and the flow rate detector 41 is covered with the potting resin 410, and the connecting portion 431 between the circuit board 30 and the pressure detector 43 and the connecting portion 441 between the circuit board 30 and the pressure detector 44 are covered with the potting resins 430 and 440, respectively. According to this, the flow rate detector 41 and the pressure detectors 43 and 44 can be sufficiently protected, and the measurement accuracy of the physical quantity of the measurement target fluid by the sensing elements 40 can be improved.

In particular, the physical quantity measuring device 10 has the first restricting portion 50 in the vicinity of the mounting area 330 of the circuit board 30 on which the flow rate detector 41 is mounted. The first restricting portion 50 restricts the potting resin 410 from wetting and spreading out. In addition, the physical quantity measuring device 10 has the second restricting portion 60 in the vicinity of the mounting areas 311 and 312 on which the pressure detectors 43 and 44 are mounted. The second restricting portion 60 restricts the potting resins 430 and 440 from wetting and spreading out.

According to this, the first restricting portion 50 and the second restricting portion 60 disposed on the circuit board 30 restrict the potting resin 410, 430 and 440 from wetting and spreading out. Therefore, it is possible to suppress the increase in the size of the circuit board 30 due to the wet spread of the potting resins 410, 430, and 440 and variations in the wet edges 410a, 430a, and 440a, and to reduce the size of the circuit board 30.

Therefore, according to the physical quantity measuring device 10 of the present embodiment, it is possible to suppress the increase in the size of the circuit board 30 even if the potting resins 410, 430, and 440 are used for connecting the sensing elements 40.

If the circuit board 30 can be downsized, the physical quantity measuring device 10 can be downsized, so that the pressure loss of the intake pipe 2 due to the physical quantity measuring device 10 can be reduced. That is, according to the physical quantity measuring device 10 of the present embodiment, it is possible to reduce the pressure loss of the intake pipe 2. Further, if the circuit board 30 can be downsized, the amount of materials constituting the physical quantity measuring device 10 can be reduced, so that the cost can be reduced.

Specifically, the first restricting portion 50 is formed of the first stepped portion 51 that protrudes toward the flow rate detector 41 from the vicinity of the mounting area 330 on which the flow rate detector 41 is mounted beyond the mounting area 330 in the plate vertical direction DRv. The first stepped portion 51 is formed of the first protrusion 511 that protrudes toward the first sub-passage 24.

Further, the second restricting portion 60 is formed of the second stepped portion 61 that protrudes toward the pressure detectors 43, 44 from the vicinity of the mounting areas 311, 312 on which the pressure detectors 43, 44 are mounted beyond the mounting areas 311 and 312 in the plate vertical direction DRv. The second stepped portion 61 is formed of the second protrusion 611 protruding toward the second sub-passage 25.

When the first restricting portion 50 and the second restricting portion 60 are formed of the stepped portions located on the circuit board 30 as described above, changes from the current circuit board 30 are small, and this can be realized at low cost.

Further, when each of the stepped portions 51 and 61 is formed by causing the vicinity of the mounting area 330, 311, and 312 to have a height higher than that of the mounting area 330, 311 and 312, the movement of the potting resin 410, 430, and 440 is restricted at the vicinity of the mounting area 330, 311 and 312. Therefore, the wet spread of the potting resins 410, 430, and 440 can be restricted by the stepped portions 51 and 61.

In addition, when the height of the vicinity of the mounting area 330, 311 and 312 is higher than that of the mounting area 330, 311 and 312, the exposure of the potting resin 410, 430 and 440 to the passage is reduced. Thus, the potting resin 410, 430, 440 is less likely to come into contact with foreign matters. As a result, deterioration of the potting resins 410, 430, and 440 due to foreign matters can be suppressed.

In the physical quantity measuring device 10, the flow rate detector 41 is arranged in the first sub-passage 24, and the pressure detectors 43 and 44 are arranged in the second sub-passage 25. By arranging the sensing elements 40 in the sub-passages 24 and 25 as described above, the physical quantity of the measurement target fluid flowing through the sub-passages 24 and 25 can be measured.

Specifically, the first sub-passage 24 includes the sub main passage 241 through which the measurement target fluid flows and the sub branching passage 242 branching off from the sub main passage 241. The sub main passage 241 has the curved portion 241d that curves away from the sub branching passage 242. The flow rate detector 41 of the sensing elements 40 is arranged in the sub main passage 241.

When a foreign matter flows into the first sub-passage 24 together with the measurement target fluid, the foreign matter is likely to flow straight through the first sub-passage 24 due to its inertia, and is less likely to flow into the sub main passage 241 having the curved portion 241d. Therefore, when the flow rate detector 41 is arranged in the sub main passage 241 having the curved portion 241d, it is possible to suppress damage to the element and deterioration of the potting resin 410 due to foreign matters.

In addition, in the first sub-passage 24, the passage area S1 of the arranging portion 241e in which the flow rate detector 41 is arranged is smaller than the passage area S2 of the upstream portion 241f located upstream of the arranging portion 241e. According to this, the flow velocity of the measurement target fluid increases at the arranging portion 241e where the flow rate detector 41 is arranged, so that foreign matters are discharged to the downstream side of the flow rate detector 41 together with the measurement target fluid by the suction action of the high-speed airflow.

Further, the first pressure detector 43 and the second pressure detector 44 are arranged side by side on the main body portion 31 of the circuit board 30. The second restricting portion 60 is disposed on the main body portion of the circuit board 30 between the mounting areas 311 and 312 on which the pressure detectors 43 and 44 adjacent to each other are mounted.

According to this, since the second restricting portion 60 is provided between the mounting areas 311 and 312 of the adjacent pressure detectors 43 and 44, the adjacent pressure detectors 43 and 44 can be arranged in close proximity to each other and the density of the pressure detectors 43, 44 can be increased.

Further, the first restricting portion 50 is disposed on the circuit board 30 to surround the mounting area 330. The inside of the first restricting portion 50 is filled with the potting resin 410. According to this, the first restricting portion 50 disposed on the circuit board 30 can sufficiently restrict the potting resin 410 from wetting and spreading out. In addition, even if the temperature of the manufacturing environment changes, the wet edge 410a of the potting resin 410 can be limited to the inside of the first restricting portion 50. As a result, it is possible to improve the robustness of the manufacturing environment temperature, reduce the cost of the manufacturing equipment, and improve the reliability.

### First Modification of First Embodiment

In the above-mentioned first embodiment, the connecting portion 431 of the first pressure detector 43 and the connecting portion 441 of the second pressure detector 44 are respectively covered with the potting resins 430 and 440. However, the physical quantity measuring device 10 is not limited to this. In the physical quantity measuring device 10, only one of the connection portions of the pressure detectors 43, 44 may be protected by the potting resin. For example, as shown in FIG. 7, in the physical quantity measuring device 10, only the connecting portion 441 of the second pressure detector 44 may be covered with the potting resin 440.

### Second Modification of First Embodiment

In the above-mentioned first embodiment, the second restricting portion 60 is formed of the second stepped portion 61 formed between the first mounting area 311 and the second mounting area 312. However, the arrangement of the second restricting portion 60 is not limited to this. As shown in FIG. 8, the second restricting portion 60 may be formed of a second stepped portion 61A arranged to surround the entire circumference of each of the first mounting area 311 and the second mounting area 312. According to this, the wet edges 430a and 440a of the potting resins 430 and 440 can be limited to the inside of the second restricting portion 60. As a result, it is possible to improve the robustness of the manufacturing environment temperature, reduce the cost of the manufacturing equipment, and improve the reliability.

### Third Modification of First Embodiment

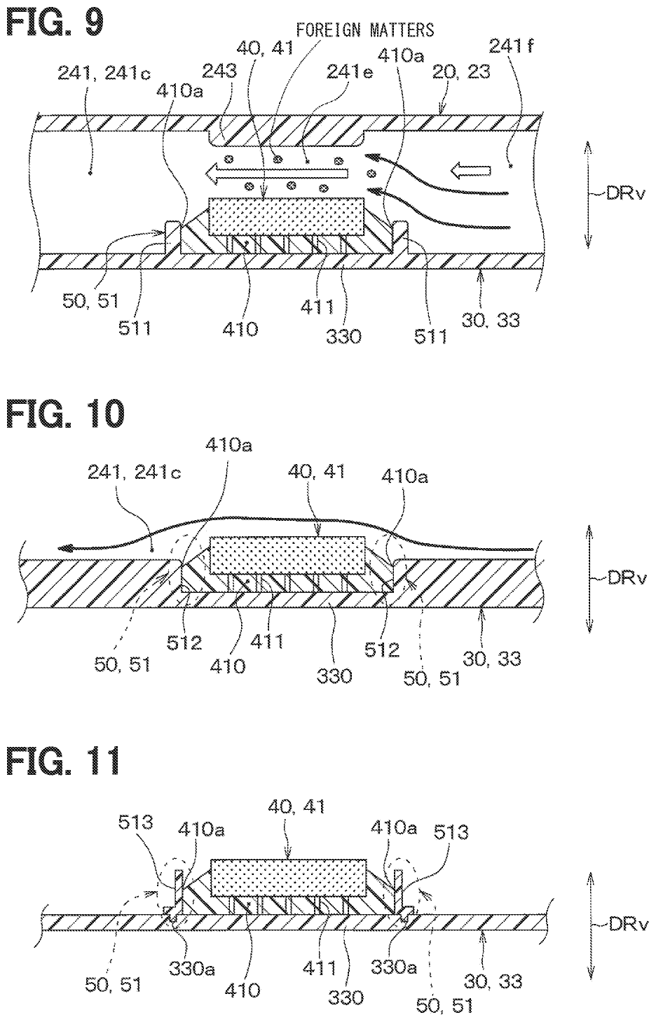

In the above-mentioned first embodiment, the flow rate detector 41 is arranged to protrude toward the center of the sub main passage 241 so that the passage area of the arranging portion 241e in the first sub-passage 24 is reduced. However, the passage shape of the first sub-passage 24 is not limited to this. As shown in FIG. 9, the first sub-passage 24 may include a protruding portion 243 protruding from a portion facing the arranging portion 241e toward the center of the sub main passage 241 such that the passage area of the arranging portion 241e is reduced due to the protruding portion 243 and the flow rate detector 41.

### Other Modifications of First Embodiment

In the above-mentioned first embodiment, the structures that restrict the potting resin 430 covering a part of the flow rate detector 41 and the potting resins 440 covering a part of the pressure detectors 43, 44 from wetting and spreading out. However, the physical quantity measuring device 10 is not limited to this.

The physical quantity measuring device 10 may have a structure that restricts a potting resin for at least one of the sensing elements 40 from wetting and spreading out. For example, the physical quantity measuring device 10 may have a structure in which one of the first restricting portion 50 and the second restricting portion 60 is omitted.

Further, the physical quantity measuring device 10 may additionally include a restricting portion that restricts a potting resin covering a part of the temperature detector 42 and a potting resin covering a part of the humidity detector 45 from wetting and spreading out.

In the above-mentioned first embodiment, the first restricting portion 50 is formed of the first stepped portion 51 surrounding the entire circumference of the mounting area 330. However, the first restricting portion 50 is not limited to this. The first restricting portion 50 may be formed of a first stepped portion 51 that partially surrounds the circumference of the mounting area 330.

### Second Embodiment

Next, a second embodiment will be described with reference to FIG. 10. In the present embodiment, differences from the first embodiment will be mainly described.

As shown in FIG. 10, the first stepped portion 51 forming the first restricting portion 50 is formed by protruding the vicinity of the mounting area 330 toward the flow rate detector 41 beyond the mounting area 330 in the plate vertical direction DRv.

Specifically, in the circuit board 30, the thickness of the mounting area 330 of the flow rate detector 41 is thinner than the thickness around the mounting area 330. In other words, the thickness of the circuit board 30 around the mounting area 330 of the flow rate detector 41 is thicker than the thickness of the mounting area 330.

As a result, the circuit board 30 has a first recess 512 having the mounting area 330 of the flow rate detector 41 as the bottom surface. The first stepped portion 51 is formed of the first recess 512 formed in the circuit board 30.

The other configurations are similar to those of the first embodiment. The physical quantity measuring device 10 of the present embodiment can obtain the same effect as those of the first embodiment, which are obtained from the same or equivalent configurations as those of the first embodiment.

In particular, the first stepped portion 51 of the present embodiment is formed of the first recess 512 formed in the circuit board 30. According to this, since the first stepped portion 51 can be formed only by changing the thickness of the circuit board 30, the first stepped portion 51 can be easily realized.

In addition, by arranging the flow rate detector 41 in the first recess 512, it is possible to inhibit the flow rate detector 41 from protruding toward the center of the first sub-passage 24. That is, the upper surface of the flow rate detector 41 in the plate vertical direction DRv can be positioned closer to the vicinity of the mounting area 330. According to this, it is possible to suppress the turbulence of the measurement target fluid in the first sub-passage 24 due to the flow rate detector 41. As a result, even when the flow speed of the measurement target fluid is high, the flow rate detector 41 can accurately detect the flow rate of the measurement target fluid.

### Modification of Second Embodiment

In the above-mentioned second embodiment, the second stepped portion 61 is configured in the same manner as in the first embodiment, but the second stepped portion 61 is not limited to this. The second stepped portion 61 may be formed of recesses formed in the first mounting area 311 and the second mounting area 312 of the circuit board 30, similarly to the first stepped portion 51 described in the second embodiment.

### Third Embodiment

Next, a third embodiment will be described with reference to FIG. 11. In the present embodiment, differences from the first embodiment will be mainly described.

As shown in FIG. 11, the first stepped portion 51 forming the first restricting portion 50 is not integrally formed with the circuit board 30. The first stepped portion 51 is a protruding member 513 that is separately formed from the circuit board 30. The protruding member 513 is formed of, for example, a substantially square frame member that can surround the side surfaces of the flow rate detector 41.

The protruding member 513 is fixed to the circuit board 30 by being fit into a fitting portion 330a formed around the mounting area 330 of the circuit board 30. The fixing of the protruding member 513 to the circuit board 30 is not limited to the fitting of the protruding member 513 to the fitting portion 330a, and may be realized by, for example, joining with an adhesive or fastening with a fastening member.

The other configurations are similar to those of the first embodiment. The physical quantity measuring device 10 of the present embodiment can obtain the same effect as those of the first embodiment, which are obtained from the same or equivalent configurations as those of the first embodiment.

In particular, the first stepped portion 51 of the present embodiment is formed of the protruding member 513 that is separately formed from the circuit board 30. According to this, when a plurality of fitting portions 330a are provided on the circuit board 30, the position of the protruding member 513 can be changed according to specifications. In this case, the circuit board 30 can be generalized to reduce the cost.

### Modification of Third Embodiment

In the above-mentioned third embodiment, the second stepped portion 61 is configured in the same manner as in the first embodiment, but the second stepped portion 61 may be formed of a component that is separately formed from the circuit board 30, similarly to the first stepped portion 51 described in the third embodiment. This component may be formed of a plate member or a frame member that can cover the side surfaces of the pressure detectors 43 and 44 facing each other.

### Fourth Embodiment

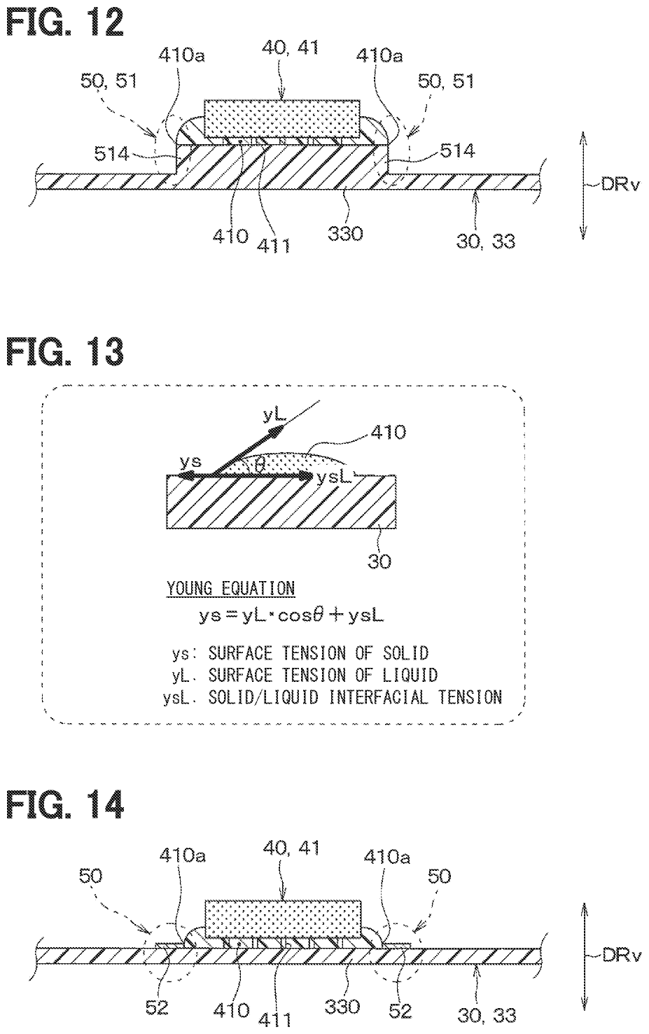

Next, a fourth embodiment will be described with reference to FIGS. 12 and 13. In the present embodiment, differences from the first embodiment will be mainly described.

As shown in FIG. 12, the first stepped portion 51 forming the first restricting portion 50 is formed by protruding the mounting area 330 toward the sensing element 40 beyond the vicinity of the mounting area 330 in the plate vertical direction DRv.

Specifically, in the circuit board 30, the thickness of the mounting area 330 of the flow rate detector 41 is thicker than the thickness around the mounting area 330. In other words, the thickness of the circuit board 30 around the mounting area 330 of the flow rate detector 41 is thinner than the thickness of the mounting area 330.

As a result, the circuit board 30 has a raised portion 514 protruding from the mounting area 330 of the flow rate detector 41 toward the center of the first sub-passage 24. The first stepped portion 51 is formed of the raised portion 514 formed on the circuit board 30.

In the physical quantity measuring device 10 of the present embodiment, the flow rate detector 41 is mounted on the raised portion 514 of the circuit board 30, and the connecting portion 411 of the flow rate detector 41 is covered with the potting resin 410.

Here, when the liquid potting resin 410 is dropped onto the solid circuit board 30, the potting resin 410 is rounded by its own surface tension and spreads outward. This phenomenon is determined by the balance of the surface tension ys of the solid, the surface tension yL of the liquid, and the interfacial tension ysL between the solid and the liquid according to Young's equation shown in FIG. 13.

When the potting resin 410 is dropped onto the raised portion 514 of the circuit board 30 to protect the connecting portion 411 of the flow rate detector 41, the wet edge 410a of the potting resin 410 is maintained at the edge of the raised portion 514. At this time, the height of the liquid film of the potting resin 410 increases due to the surface energy of the liquid film of the potting resin 410.

The other configurations are similar to those of the first embodiment. The physical quantity measuring device 10 of the present embodiment can obtain the same effect as those of the first embodiment, which are obtained from the same or equivalent configurations as those of the first embodiment.

The first stepped portion 51 of the present embodiment is formed by protruding the mounting area 330 of the flow rate detector 41 toward the flow rate detector 41, which is the sensing element 40, beyond the vicinity of the mounting area 330 in the plate vertical direction DRv. In this way, when the first stepped portion 51 is formed by causing the mounting area 330 to have a height higher than that of the vicinity of the mounting area 330, the potting resin 410 on the first stepped portion 51 is maintained inside the first stepped portion 51 due to the surface tension of the first stepped portion 51. Therefore, the first stepped portion 51 can restrict the potting resin 410 from wetting and spreading out.

### Modification of Fourth Embodiment

In the above-mentioned fourth embodiment, the second stepped portion 61 is configured in the same manner as in the first embodiment, but the second stepped portion 61 is not limited to this. The second stepped portion 61 may be configured by raising the first mounting area 311 and the second mounting area 312 of the circuit board 30, similarly to the first stepped portion 51 described in the fourth embodiment.

In the above-mentioned fourth embodiment, the raised portion 514 is integrally formed with the circuit board 30, but the relationship between the raised portion 514 and the circuit board 30 is not limited to this. The raised portion 514 may be separately formed from the circuit board 30.

### Fifth Embodiment

Next, a fifth embodiment will be described with reference to FIG. 14. Different constituents in the present embodiment from those in the first embodiment will be mainly described.

As shown in FIG. 14, the first restricting portion 50 is formed of a wiring pattern 52 formed on the circuit board 30 instead of the first stepped portion 51. The wiring pattern 52 is formed on the circuit board 30 so as to surround the flow rate detector 41.

The wiring pattern 52 is made of a material having a surface tension higher than that of the surface of the circuit board 30. The material constituting the wiring pattern 52 may be any material as long as the potting resin 410 is difficult to wet and spread on the material. For example, the wiring pattern 52 may be made of a material having a higher frictional force than the surface of the circuit board 30. The wiring pattern 52 may be formed not only by a dummy pattern but also by a pattern used for implementation.

The other configurations are the same as those of the first embodiment. The physical quantity measuring device 10 of the present embodiment can obtain the same effect as those of the first embodiment, which are obtained from the same or equivalent configurations as those of the first embodiment.

In the physical quantity measuring device 10 of the present embodiment, the first restricting portion 50 is formed of the wiring pattern 52 instead of the first stepped portion 51. Since the wiring pattern 52 is made of a material having a surface tension higher than that of the surface of the circuit board 30, it is possible to restrict the potting resin 410 from wetting and spreading out in the vicinity of the flow rate detector 41.

### Modification of Fifth Embodiment

In the above-mentioned fifth embodiment, the second restricting portion 60 is configured in the same manner as in the first embodiment, but the second restricting portion 60 is not limited to this. The second restricting portion 60 may be formed of a wiring pattern formed on the circuit board 30, similarly to the first restricting portion 50 described in the fifth embodiment.

In the fifth embodiment described above, the first restricting portion 50 is formed of the wiring pattern 52, but the first restricting portion 50 is not limited to this. The first restricting portion 50 may be formed of a paint having a higher surface tension than the surface of the circuit board 30, instead of the wiring pattern 52.

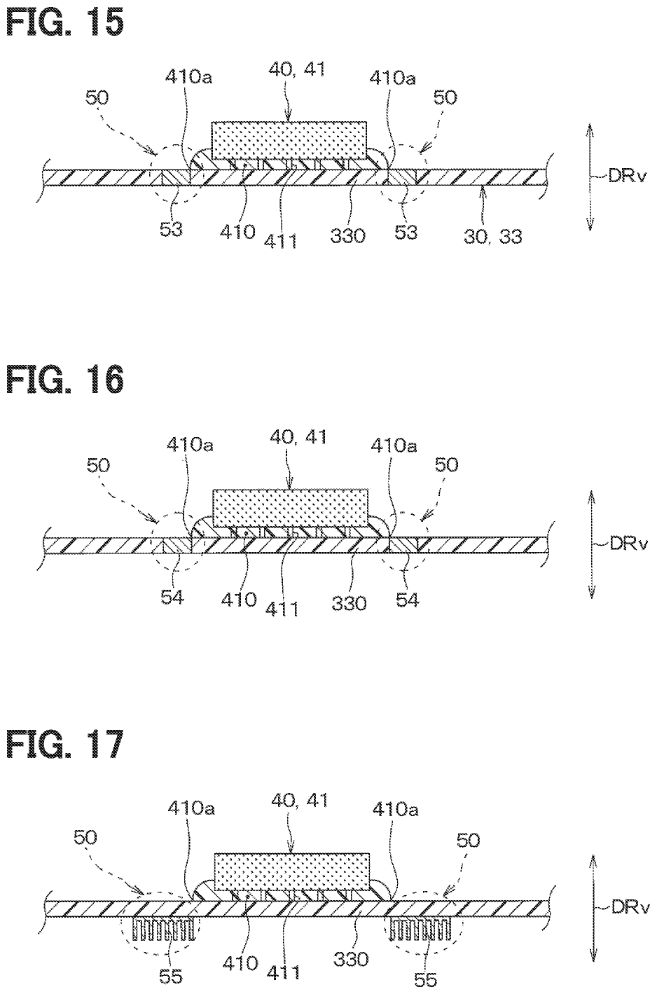

In the above-mentioned fifth embodiment, the first restricting portion 50 is configured by the wiring pattern 52 formed on the circuit board 30, but the first restricting portion 50 is not limited to this. For example, as shown in FIG. 15, the vicinity portion 53 itself of the circuit board 30 that surrounds the mounting area 330 may be made of a material having a large surface tension and the vicinity portion 53 may be used as the first restricting portion 50.

### Sixth Embodiment

Next, a sixth embodiment will be described with reference to FIG. 16. In the present embodiment, differences from the first embodiment will be mainly described.

The surface tension of a liquid decreases as the temperature increases. Therefore, when a part of the flow rate detector 41 is covered with the potting resin 410, the wet spread of the potting resin 410 near the flow rate detector 41 can be controlled by changing the temperature around the mounting area 330 of the flow rate detector 41.

As shown in FIG. 16, the first restricting portion 50 is formed of a cooling unit 54 that lowers the temperature around the mounting area 330 to lower than that of the mounting area 330. The cooling unit 54 can be formed of, for example, a Peltier element that generates cold heat by energization.

The other configurations are the same as those of the first embodiment. The physical quantity measuring device 10 of the present embodiment can obtain the same effect as those of the first embodiment, which are obtained from the same or equivalent configurations as those of the first embodiment.

In the physical quantity measuring device 10 of the present embodiment, the first restricting portion 50 is formed of the cooling unit 54 instead of the first stepped portion 51. According to this, when a part of the flow rate detector 41 is covered with the potting resin 410, the vicinity of the mounting area 330 of the flow rate detector 41 is cooled by the cooling unit 54, so that the potting resin 410 in the vicinity of the flow rate detector 41 is restricted from wetting and spreading out.

### Modification of Sixth Embodiment

In the sixth embodiment described above, the second restricting portion is configured in the same manner as in the first embodiment, but the second restricting portion 60 is not limited to this. The second restricting portion 60 may be formed of a cooling unit that cools the vicinity of the first mounting area 311 and the vicinity of the second mounting area 312, similarly to the first restricting portion 50 described in the sixth embodiment.

In the above-mentioned fifth embodiment, an example in which the first restricting portion 50 is formed of the cooling unit 54 is described, but the first restricting portion 50 is not limited to this. As shown in FIG. 17, the first restricting portion 50 may be formed of heat dissipation fins 55 provided on the back surface of the mounting area 330 of the circuit board 30, for example. Further, the first restricting portion 50 may be configured such that the potting resin 410 intentionally spread in a predetermined direction by utilizing heat generation of the circuit unit and a heater to restrict the potting resin 410 from spreading out in another direction.

### Seventh Embodiment

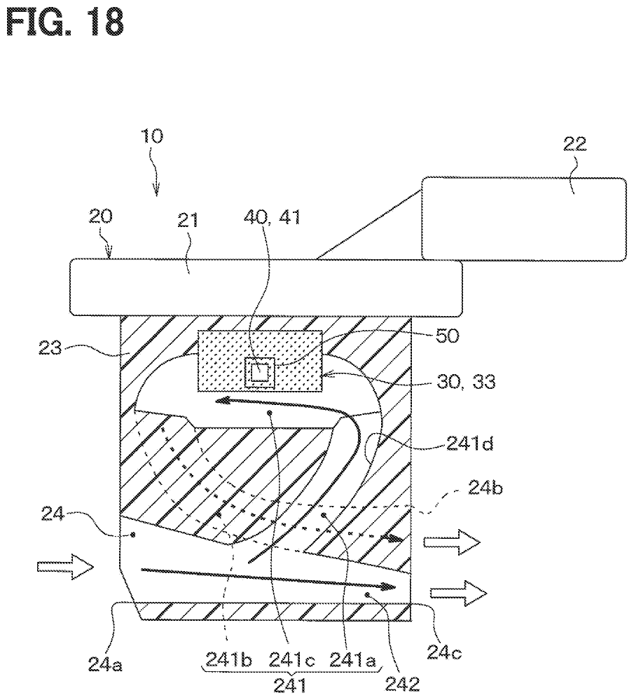

Next, a seventh embodiment will be described with reference to FIG. 18. In the present embodiment, differences from the first embodiment will be mainly described.

As shown in FIG. 18, in the measuring portion 23, the second sub-passage 25 described in the first embodiment is omitted, and the first sub-passage 24 is provided on the distal end of the measuring portion 23. Further, the circuit board 30 does not have the temperature detector 42, the pressure detectors 43, 44, and the humidity detector 45 described in the first embodiment, and the flow rate detector 41 constituting the sensing element 40 is mounted on the circuit board 30.

The other configurations are the same as those of the first embodiment. The physical quantity measuring device 10 of the present embodiment can obtain the same effect as those of the first embodiment, which are obtained from the same or equivalent configurations as those of the first embodiment.

### Eighth Embodiment

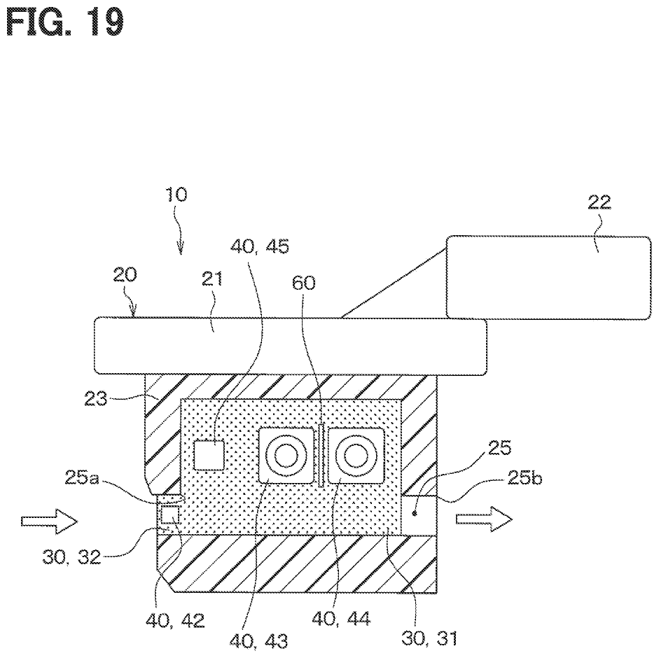

Next, an eighth embodiment will be described with reference to FIG. 19. In the present embodiment, differences from the first embodiment will be mainly described.

As shown in FIG. 19, in the measuring portion 23, the first sub-passage 24 described in the first embodiment is omitted, and the second sub-passage 25 is provided. Further, the flow rate detector 41 described in the first embodiment is not mounted on the circuit board 30, and the temperature detector 42, the pressure detectors 43, 44, and the humidity detector 45 constituting the sensing elements 40 are mounted on the circuit board 30.

The other configurations are the same as those of the first embodiment. The physical quantity measuring device 10 of the present embodiment can obtain the same effect as those of the first embodiment, which are obtained from the same or equivalent configurations as those of the first embodiment.

### Modification of Eighth Embodiment

In the above-mentioned eighth embodiment, the temperature detector 42, the pressure detectors 43, 44 and the humidity detector 45 are mounted on the circuit board 30. However, the physical quantity measuring device 10 is not limited to this. The physical quantity measuring device 10 may be equipped with, for example, one or some of the temperature detector 42, pressure detectors 43 and 44, and the humidity detector 45.

### Other Embodiments

Although the representative embodiments of the present disclosure have been described above, the present disclosure is not limited to the embodiments and can be variously modified as follows, for example.

In the above-described embodiments, the example in which the sensing elements 40 are arranged in the sub-passages 24 and 25 formed in the housing 20 is described, but the arrangement form of the sensing elements 40 is not limited to this. For example, when a part of the circuit board 30 is exposed to the outside of the housing 20, at least a part of the sensing elements 40 may be mounted on a portion of the circuit board 30 exposed to the outside of the housing 20.

As in the above embodiments, it is preferable that the arranging portion 241e in which the flow rate detector 41 is arranged is narrowed, but the present disclosure is not limited to this. The passage area of the arranging portion 241e may be about the same as that of the upstream portion 241f of the arranging portion 241e. Although not particularly mentioned in the above-described embodiments, the arranging portion in which the sensing elements 40 are arranged in the second sub-passage 25 may be narrowed.

As in the above embodiments, it is desirable that the flow rate detector 41 is arranged in the sub main passage 241 having the curved portion 241d, but the arrangement form of the flow rate detector 41 is not limited to this. For example, the flow rate detector 41 may be arranged so that at least a part of the flow rate detector 41 is located in the sub branching passage 242. Further, the first sub-passage 24 may exclude the sub branching passage 242 and only have the sub main passage 241.

In the above-described embodiments, five sensing elements 40 of the flow rate detector 41, the temperature detector 42, the pressure detectors 43 and 44, and the humidity detector 45 are mounted, but the number of the sensing elements 40 is not limited to this. In the physical quantity measuring device 10, for example, four or less sensing elements 40 may be mounted on the circuit board 30, or five or more sensing elements 40 may be mounted on the circuit board 30.

In the above-described embodiments, four types of sensing elements 40 of the flow rate detector 41, the temperature detector 42, the pressure detectors 43 and 44, and the humidity detector 45 are mounted, but the types of the sensing elements 40 are not limited to these. In the physical quantity measuring device 10, for example, three or less types of sensing elements 40 may be mounted on the circuit board 30, or five or more types of sensing elements 40 may be mounted on the circuit board 30.

In the above-described embodiment, an example in which the physical quantity measuring device 10 is applied to the internal combustion engine control system has been described, but the physical quantity measuring device 10 can be applied to various systems other than the internal combustion engine control system.

In the above embodiments, it goes without saying that the components constituting the embodiments are not necessarily indispensable unless otherwise clearly stated or unless otherwise thought to be clearly indispensable in principle.

In the above embodiments, when a numerical value such as the number, a numerical value, an amount, or a range of the component of the embodiment is mentioned, the numerical value is not limited to the specified number unless otherwise specified to be indispensable or clearly limited to the specified number in principle.

In the above embodiments, when a shape, a positional relationship, or the like is mentioned, the shape, the positional relationship, or the like is not limited to that being mentioned unless otherwise specified or limited to a specified shape, a specified positional relationship, or the like in principle.

### Overview

According to the first aspect shown in a part or all of the above-described embodiment, a physical quantity measuring device includes a housing, a sensing element configured to detect a physical quantity of a measurement target fluid, and a circuit board disposed in the housing and having a mounting area on which the sensing element is mounted. The physical quantity measuring device further includes a potting resin covering an electric connecting portion between the circuit board and the sensing element, and a restricting portion disposed on the circuit board in a vicinity of the mounting area to restrict the potting resin from wetting and spreading out.

According to the second aspect, when a plate vertical direction is defined as a direction that is perpendicular to a plate surface of the circuit board, the restricting portion includes a stepped portion that causes the vicinity of the mounting area to have a different height in the plate vertical direction from that of the mounting area.

In this way, by causing the vicinity of the mounting area to have a different height from that of the mounting area, the potting resin can be restricted from wetting and spreading out. The restricting portion forms a step on the circuit board. Since there is a little change from the current circuit board or the like, there is an advantage that the restricting portion is easily realized.

According to the third aspect, the stepped portion is a protrusion protruding from the vicinity of the mounting area toward the sensing element beyond the mounting area in the plate vertical direction.

When the stepped portion is formed by causing the vicinity of the mounting area to have a height higher than that of the mounting area, the movement of the potting resin is restricted by the vicinity of the mounting area, so that the stepped portion can restrict the wet spread of the potting resin.

In addition, when the height of the vicinity of the mounting area is higher than that of the mounting area, the exposure of the potting resin to the passage is reduced and the potting resin is less likely to come into contact with foreign matters, so that deterioration of the potting resin due to foreign matters can be suppressed.

According to the fourth aspect, the stepped portion is a protrusion protruding from the mounting area toward the sensing element beyond the vicinity of the mounting area in the plate vertical direction.

When the stepped portion is formed by causing the mounting area to have a height higher than that of the vicinity of the mounting area, the potting resin near the stepped portion is maintained inside the stepped portion due to surface tension, so that the stepped portion can restrict the potting resin from wetting and spreading out. The height of the potting resin in the plate vertical direction increases by the amount of the surface energy of the potting resin.

According to the fifth aspect, the housing defines a sub-passage through which a part of the measurement target fluid flowing through the main passage flows. The sensing element is arranged in the sub-passage. By arranging the sensing element in the sub-passage in this way, the physical quantity of the measurement target fluid flowing through the sub-passage can be measured.

According to the sixth aspect, the sub-passage includes a sub-main passage through which the measurement target fluid flows and a sub branching passage branching off from the sub-main passage. The sub-main passage has a curved portion curvedly extending in a direction away from the sub branching passage. The sensing element is arranged in the sub-main passage.

When a foreign matter flows into the sub-passage together with the measurement target fluid, the foreign matter easily flows straight through the sub-passage due to its inertia, and is less likely to flow into the sub-main passage having the curved portion. Therefore, when the sensing element is arranged in the sub main passage having the curved portion, it is possible to suppress damage to the element due to foreign matters and deterioration of the potting resin due to foreign matters.

According to the seventh aspect, the sub-passage has an arranging portion in which the sensing element is arranged. A passage area of the arranging portion is less than a passage area of an upstream portion of the arranging portion. According to this, the passage area decreases at the arranging portion in which the sensing element is disposed, so that the flow velocity of the measurement target fluid increases at the arranging portion and foreign matters can be discharged to the downstream side of the sensing element together with the measurement target fluid due to the suction action of the high speed airflow.

According to the eighth aspect, the sensing element is a plurality of sensing elements, and the restricting portion is disposed on the circuit board between mounting areas on which adjacent ones of the plurality of sensing elements are mounted. According to this, since the restricting portion is disposed between the adjacent mounting areas of the sensing elements, it is possible to arrange the adjacent sensing elements in close proximity to each other and to increase the density of the sensing elements.

According to the ninth aspect, the restricting portion is disposed on the circuit board to surround the mounting area. An inside of the restricting portion is filled with the potting resin. According to this, the restricting portion disposed on the circuit board can sufficiently restrict the potting resin from wetting and spreading out.

What is claimed is:

1. A physical quantity measuring device, comprising:
a housing having a part disposed in a main passage through which a measurement target fluid flows;
a sensing element configured to detect a physical quantity of the measurement target fluid;
a circuit board disposed in the housing and having a mounting area on which the sensing element is mounted;
a potting resin applied to the circuit board and covering an electric connecting portion between the circuit board and the sensing element; and
a restricting portion disposed on the circuit board in a vicinity of the mounting area to restrict the potting resin from wetting and spreading out when the potting resin is applied to the circuit board.

2. The physical quantity measuring device according to claim 1, wherein
a plate vertical direction is defined as a direction that is perpendicular to a plate surface of the circuit board, and
the restricting portion includes a stepped portion that causes the vicinity of the mounting area to have a height in the plate vertical direction different from that of the mounting area.

3. The physical quantity measuring device according to claim 2, wherein
the stepped portion is a protrusion protruding from the vicinity of the mounting area toward the sensing element beyond the mounting area in the plate vertical direction.

4. The physical quantity measuring device according to claim 2, wherein
the stepped portion is a protrusion protruding from the mounting area toward the sensing element beyond the vicinity of the mounting area in the plate vertical direction.

5. The physical quantity measuring device according claim 1, wherein
the housing defines a sub-passage through which a part of the measurement target fluid flowing through the main passage flows, and
the sensing element is disposed in the sub-passage.

6. The physical quantity measuring device according to claim 5, wherein
the sub-passage includes a sub main passage through which the measurement target fluid flows and a sub branching passage branching off from the sub main passage,
the sub main passage includes a curved portion curvedly extending in a direction away from the sub branching passage, and
the sensing element is disposed in the sub main passage.

7. The physical quantity measuring device according to claim 5, wherein
the sub-passage has an arranging portion in which the sensing element is arranged, and
a passage area of the arranging portion is less than a passage area of an upstream portion of the arranging portion.

8. The physical quantity measuring device according to claim 1, wherein
the sensing element is a plurality of sensing elements,
the restricting portion is disposed on the circuit board between mounting areas on which adjacent ones of the plurality of sensing elements are mounted.

9. The physical quantity measuring device according to claim 1, wherein
the restricting portion is disposed on the circuit board to surround the mounting area, and
an inside of the restricting portion is filled with the potting resin.

10. The physical quantity measuring device according to claim 1, wherein
the restricting portion includes a wiring pattern formed on the circuit board, and
the wiring pattern is made of a material having a surface tension or a frictional force that is greater than that of a board surface of the circuit board.
